(19) United States
(12) Patent Application Publication
(10) Pub. No.: US 2008/0222472 A1
(43) Pub. Date: Sep. 11, 2008

(54) METHOD FOR AUTOMATIC TEST PATTERN GENERATION FOR ONE TEST CONSTRAINT AT A TIME

(76) Inventors: Gary D. Grise, Colchester, VT (US); Vikram Iyengar, South Burlington, VT (US); Mark R. Taylor, Essex Junction, VT (US)

Correspondence Address: CANTOR COLBURN LLP-IBM BURLINGTON, 20 Church Street, 22nd Floor, Hartford, CT, 06103, US

(21) Appl. No.: 11/684,242

(22) Filed: Mar. 9, 2007

(51) Int. Cl. G01R 31/28

(52) U.S. Cl. 714/738

(57) ABSTRACT

A method for automatically generating test patterns for an IC device includes initially generating a subset of available test patterns according to each of a plurality of test constraints for the IC device, determining an incremental amount of total test coverage of the IC device attributable to each of the test constraints as a result of the initially generated subset of test patterns therefor; determining the test constraint initially providing the largest amount of incremental test coverage, and thereafter generating another subset of test patterns therefor; and iteratively determining the current test constraint providing the largest amount of incremental test coverage, and continuing to generate additional test patterns therefor until one or more test exit criteria is reached.

### BACKGROUND

The present invention relates generally to integrated circuit (IC) device testing techniques and, more particularly, to a method for maximizing at-speed structural test coverage by testing one clock domain at a time.

The testing of ICs has evolved into a highly developed area of technology. Generally such testing may be implemented through the use of external test equipment, Built-In Self-Test (BIST) circuitry, or a combination of the two. Typically, all test methodologies involve shifting data into scannable memory elements of an IC device (e.g., Level Sensitive Scan Design or LSSD latches), capturing the input to the memory elements, shifting the captured data out and then comparing the captured data with predetermined values to determine whether the circuit has performed according to design. Automatic test pattern generation (ATPG) systems use software tools for testing digital circuits after the circuits have been manufactured. In general, an ATPG tool generates a set of test vectors that are applied to a circuit under test. The output of the circuit is analyzed to identify logic faults in the circuit design (i.e., “functional testing”), as well as detecting fabrication defects (i.e., “structural testing”).

“At-speed” testing refers to testing techniques to detect defects that are only apparent when the circuit is running at system speed. Many time-based defects cannot be detected unless the circuit is run at-speed. Examples of time related defects that occur at-speed include high impedance shorts, in-line resistance, and cross talk between signals. One problem of particular concern in regard to at-speed structural testing (ASST) relates to the effects of clock skew (i.e., misalignment of clock signals between clock domains) when signals are exchanged between different clock domains in the circuit at high test-clock speeds. The testing of multiple asynchronous clock domains simultaneously while using functional clocks generated by phase locked loops (PLLs) is difficult because it is impossible to predict the relative positions of clock edges generated by asynchronous PLLs. Existing solutions to the problem of testing a circuit having multiple asynchronous clock domains include testing only one clock domain at a time.

In the case of “one domain at a time” testing, there is the issue of how to optimally divide a given limited test pattern budget among several different logic domains. One simplistic solution is to simply divide the total number of available test patterns (limited by the tester memory capacity) equally among the several domains. However, this approach does not take into account the sizes of various domains. Alternatively, the pattern budget could be divided according to domain size (number of faults). On the other hand, it is possible that certain logic domains having few faults may still need a relatively high number of test patterns.

Still another approach is to generate test patterns for each domain and plot test coverage curves that reflect the fault coverage (percent of determined faults/actual faults as a function of the number of generated test patterns). As the curves begin to flatten over an increased number of generated test patterns (signifying diminishing returns), the generated test patterns can then be cut off. However, a decision must still be made as to where any such cut off point lies (e.g., 85%, 95%, 99%, 99.99%, etc.). If the selected cut off point of the coverage is too low, the testing is not robust. Conversely, if the selected cut off point is too high, then it is likely the number of test patterns required for that level of coverage exceeds the amount of patterns available due to the tester's memory capacity.

The problem can be generalized to that of maximizing the test coverage by performing ATPG to produce one subset of constrained tests at a time. A constrained test is a test that is generated by restricting the ATPG according to a particular test constraint. An example of a test constraint could be to restrict the ATPG to generate a test pattern to test only a certain clock domain on the IC, or to restrict the ATPG to a certain test mode, or to restrict the ATPG to test a certain IC partition, or to restrict the ATPG to use a certain test pattern generation algorithm. Hence, a constrained test pattern is one that addresses a certain clock domain, or uses a certain test mode, or tests a certain IC partition, or uses a certain test pattern generation algorithm, to name a few types of constrained tests.

Accordingly, it would be desirable to be able to implement a methodology that maximizes the final test coverage across various types of test constraints, such as asynchronous clock boundaries, circuit partitions, test modes or test generation algorithms, to name a few.

### SUMMARY

The foregoing discussed drawbacks and deficiencies of the prior art are overcome or alleviated by a method for automatically generating test patterns for an IC device. In an exemplary embodiment, the method includes initially generating for the IC device a subset of available test patterns according to each of a plurality of test constraints, determining an incremental amount of total test coverage of the IC device attributable to each of the test constraints as a result of the initially generated subset of test patterns therefor; determining the test constraint initially providing the largest amount of incremental test coverage, and thereafter generating another subset of test patterns therefor; and iteratively determining the current test constraint providing the largest amount of incremental test coverage, and continuing to generate additional test patterns therefor until one or more test exit criteria is reached. In this embodiment, test patterns are added to the final test set as soon as they are generated.

In another embodiment, a method for generating test patterns for an IC device includes initializing a total test coverage amount, T, of the IC device to zero, wherein T represents a ratio of total tested faults of the IC device to an actual number of faults of the IC device; initially generating a subset, t, of a maximum number, P, of available test patterns for each of a number, N, of test constraints of the IC device; accumulating a running total, p, of generated test patterns to the IC upon generation of the t test patterns for each of the N test constraints, and adding each generated subset of t test patterns to a final test set for the IC device; determining a new total test coverage value, Tn, upon each generation of t test patterns; determining an incremental amount of total test coverage of the IC device attributable to each of the test constraints as a result of the generated subset of test patterns therefor, wherein the incremental amount of total test coverage, T(i) of a given test constraint, i, is determined by the difference between the new total test coverage value and the previous total test coverage amount, T, such that T(i)=Tn−T; updating the total test coverage amount, T, to reflect the new total test coverage value, Tn, such that T=Tn; identifying a specific test constraint, i, initially providing the largest amount of incremental test coverage, T(i), with respect to the other test constraints, and thereafter generating another subset of t test patterns therefor; and iteratively determining the current test constraint providing the largest amount of incremental test coverage, and continuing to generate additional t test patterns therefor until one or more test exit criteria is reached.

In still another embodiment, a method for automatically generating test patterns for an IC device includes initially generating a subset of available test patterns for each of a plurality of test constraints for the IC device; determining an incremental amount of total test coverage of the IC device attributable to each of the subsets of constrained test patterns as a result of the initially generated subsets of test patterns; determining the test constraint initially providing the largest amount of incremental test coverage, and adding its subset of patterns to a final test set; and continuing to iteratively generate an additional subset of patterns for each test constraint, and determining the test constraint providing the largest amount of incremental test coverage, and adding its subset of patterns to the final test set, until one or more test exit criteria is reached.

In still another embodiment, a method for generating test patterns for an IC device includes initializing a total test coverage amount, T, of the IC device to zero, wherein T represents a ratio of total tested faults of the IC device to an actual number of faults of the IC device; initially generating a subset, t, of a maximum number, P, of available test patterns for each of a number, N, of test constraints of the IC device; adding each generated subset of t test patterns to a final test set for the IC device, and accumulating a running total, p, of added test patterns to the IC upon addition of the t test patterns for each of the N test constraints; determining a new total test coverage value, Tn, upon each generation of t test patterns; determining an incremental amount of total test coverage of the IC device attributable to each of the test constraints as a result of the generated subset of test patterns therefor, wherein the incremental amount of total test coverage, T(i), of a given test constraint, i, is determined by the difference between the new total test coverage value and the previous total test coverage amount, T, such that T(i)=Tn−T; updating the total test coverage amount, T, to reflect the new total test coverage value, Tn, such that T=Tn; again generating a subset, t, of a maximum number, P, of available test patterns for each of a number, N, of test constraints of the IC device, and identifying a specific test constraint, i, providing the largest amount of incremental test coverage, T(i), with respect to the other test constraints, adding only the subset of patterns generated for test constraint i to the final test set, and incrementing p by the number t of test patterns added to the final test set; iteratively generating a subset, t, of a maximum number, P, of available test patterns for each of a number, N, of test constraints of the IC device, identifying a specific test constraint, i, providing the largest amount of incremental test coverage, T(i), with respect to the other test constraints, adding only the subset of patterns generated for test constraint i to the final test set, and incrementing p by the number t of test patterns added to the final test set until one or more test exit criteria is reached.

### BRIEF DESCRIPTION OF THE DRAWINGS

Referring to the exemplary drawings wherein like elements are numbered alike in the several Figures:

FIG. 1 is a schematic block diagram of an exemplary IC device having a plurality of clock domains, which are tested at-speed one at a time;

FIG. 2 is an illustration of a test coverage curve for a clock domain;

FIG. 3 is a high-level process flow diagram illustrating a method for maximizing at-speed structural test coverage by generating test patterns according to one test constraint at a time, in accordance with an exemplary embodiment of the invention;

FIGS. 4(a) and 4(b) are a flowchart illustrating one possible detailed implementation of the method in FIG. 3;

FIG. 5 is a high-level process flow diagram illustrating a method for maximizing at-speed structural test coverage by generating test patterns according to one test constraint at a time, in accordance with another exemplary embodiment of the invention; and

FIGS. 6(a) and 6(b) are a flowchart illustrating one possible detailed implementation of the method in FIG. 5.

### DETAILED DESCRIPTION

Disclosed herein is a method for maximizing the total test coverage of an IC device by generating one subset of constrained tests at a time. Briefly stated, the method performs automatic test pattern generation in stages by generating a small subset of patterns according to the various test constraints, such that the particular test constraint (e.g., addressing or using a particular clock domain, circuit partition, test mode, test generation algorithm, etc.) that contributes the most to the total test coverage receives the next subset of patterns thereto. By continually evaluating the test coverage of each subset of constrained tests, the “best performer” receives the next set of patterns until one or more thresholds has been reached which terminates the test pattern generation.

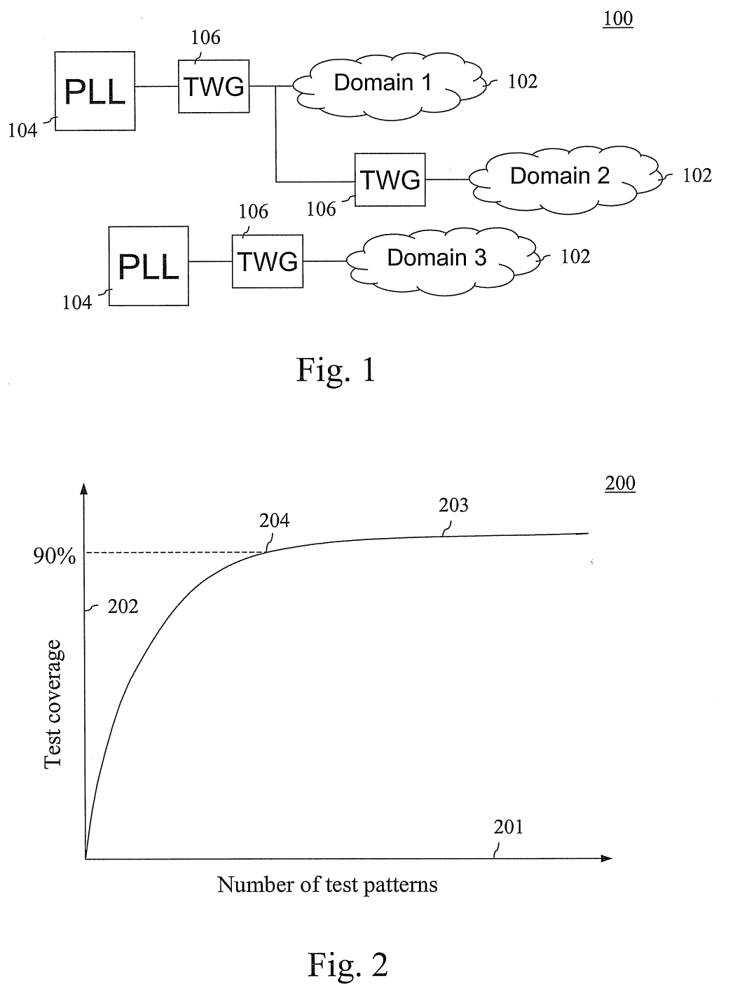

It will be noted that the terms “domain” and “clock domain” are used interchangeably hereinafter. Referring initially to FIG. 1, there is shown a schematic block diagram of an exemplary IC device 100 having a plurality of partitions 102 (e.g., clock domains), which are tested at-speed one at a time. In the simple example depicted, the IC device 100 includes a plurality of phased locked loops (PLL) 104 for generating oscillating clock pulses, as well as a plurality of test waveform generators 106 that generate constrained clock pulses used in the at-speed testing of elements within the associated testing domains 102. In particular, the blocks 106 labeled TWG refer to a test waveform generator that would constrain the PLL output clock waveform, such that only one domain is tested per test pattern. It will be appreciated that although FIG. 1 illustrates test constraints corresponding to a plurality of clock domains, the present method embodiments described herein are equally applicable to other types of test constraints including, but not limited to: asynchronous clock boundaries, circuit partitions, test modes and test generation algorithms.

FIG. 2 is an illustration of an exemplary test coverage curve 200 for Domain 1 in IC device 100 of FIG. 1. The X-axis 201 represents the number of test patterns generated for the domain, while the Y-axis 202 represents the total test coverage (in percentage). Curve 203 illustrates the corresponding increase in total test coverage as the number of patterns generated is increased. Point 204 on curve 203 shows the point at which 90% test coverage is achieved for Domain 1. It will be appreciated that although FIG. 2 illustrates the test coverage curve for a domain, similar test coverage curves can be constructed for test patterns generated according to other types of test constraints including, but not limited to: circuit partitions, test modes and test generation algorithms.

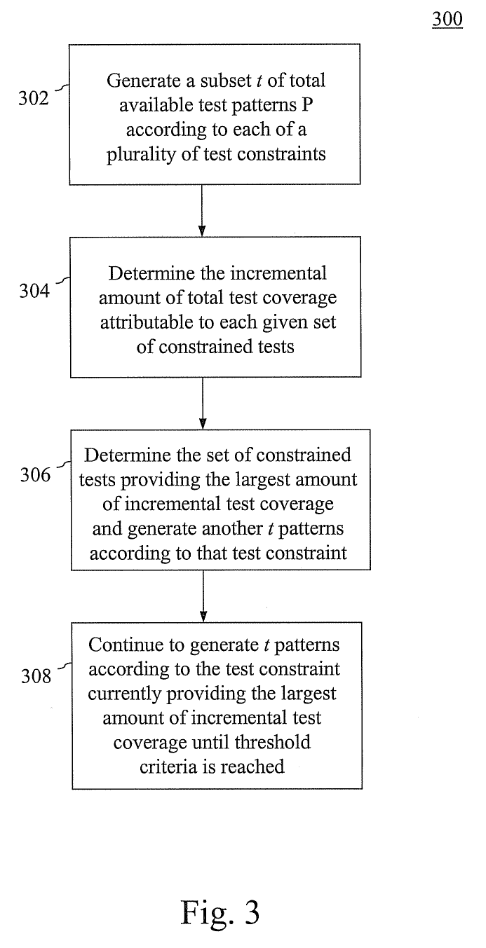

Accordingly, FIG. 3 is a high-level process flow diagram illustrating a method 300 for maximizing the total test coverage for the IC device by generating test patterns according to one test constraint at a time, in accordance with an exemplary embodiment of the invention. In the description that follows, the term “clock domains” is used to represent test constraints for purposes of simplicity. It will therefore be appreciated that other types of test constraints may be substituted in the following description, without departing from the scope of the invention.

As initially shown in block 302, the method 300 begins by generating a subset, t, of the total number of test patterns according to each of a plurality of test constraints. In the simple example of FIG. 1, each test constraint corresponds to a particular clock domain of the IC device, and the total number, N, of domains (e.g., asynchronous clock domains) is equal to 3. An exemplary maximum number of test patterns for purposes of illustration may be on the order of about 21,000. Thus, rather than simply dividing the total and generating 7,000 patterns for each domain, a relatively small subset (e.g., 32) is initially generated for each domain. After t patterns are generated for each of the domains, the resulting incremental chip test coverage attributable to each domain is determined, as shown in block 304. The term “test coverage” is a ratio or percentage of tested faults (through test pattern generation) to the total number of actual faults on the IC device.

As a practical matter, the lower limit on t would be 1, in which case 1 test pattern per test constraint would be generated at a time. The lower the value of t, the more fine-grained the optimization, since each pattern would be generated according to the current test constraint providing the most effective coverage return. The upper limit on t would be given by P-N+1, such that even if the largest possible number of patterns (i.e., P-N+1) is generated first for a certain test constraint, each remaining test constraint will still receive at least 1 test pattern.

An underlying principle of the inventive embodiment is the subsequent generation/allocation of additional test patterns to that test constraint that yields the largest incremental test coverage, as reflected in block 306. Thus, in the simplified example used herein, if the generation of 32 test patterns for each of Domains 1, 2 and 3 of FIG. 1 resulted in incremental test coverages of 2% for Domain 1, 7% for Domain 2 and 5% for Domain 3, then Domain 2 has provided the largest incremental test coverage. Therefore, another 32 test patterns would be generated for Domain 2, and the resulting incremental test coverage due to this generation would be determined.

If, for example, the result of the generation of the additional 32 test patterns to Domain 2 resulted in an additional incremental test coverage of 6%, then Domain 2 still yields the largest incremental test coverage, and would once again be the recipient of the next set of t (e.g., 32) test patterns. On the other hand, if the result of the generation of the additional 32 test patterns to Domain 2 resulted in an incremental test coverage of only 4%, then Domain 2 no longer yields the largest incremental test coverage at this point; instead, Domain 3 (at 5%) is now the leader in incremental test coverage. In this case, the next set of patterns would be generated for Domain 3.

As reflected in block 308, the process is iteratively repeated by generating a subset of patterns for the domain currently providing the largest incremental test coverage until one or more threshold criteria is reached. Such criteria may include, for example: the total number of generated test patterns equaling or exceeding a selected maximum value; the total test coverage from all of the generated patterns equaling or exceeding a selected maximum value; the largest incremental test coverage among the domains falling below a selected minimum value. In this manner, the respective performance of the domains is repeatedly evaluated, so that the test patterns can be more efficiently distributed.

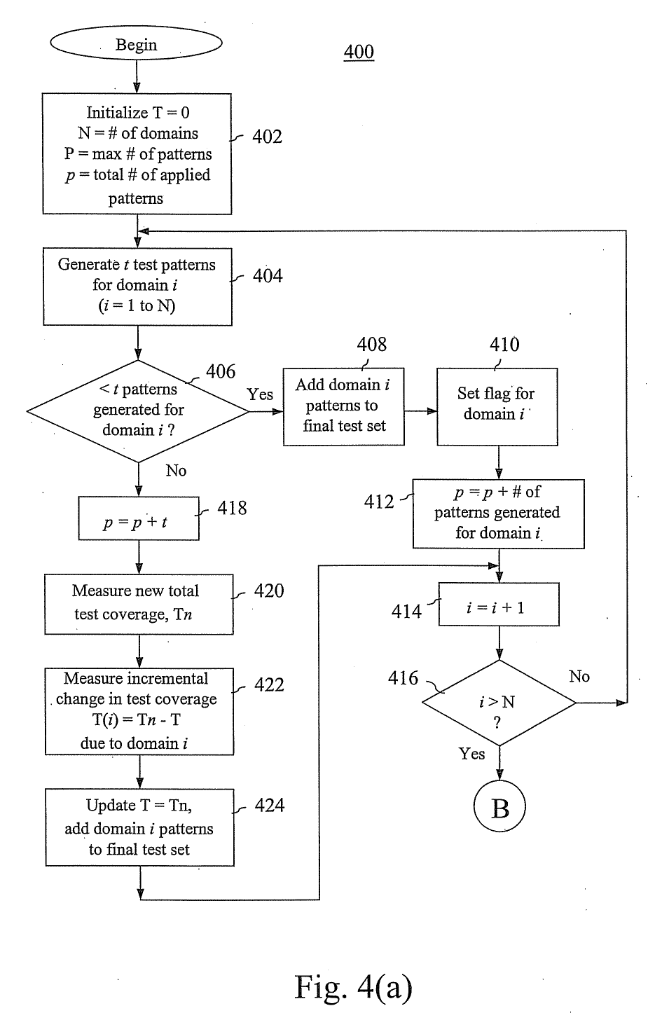

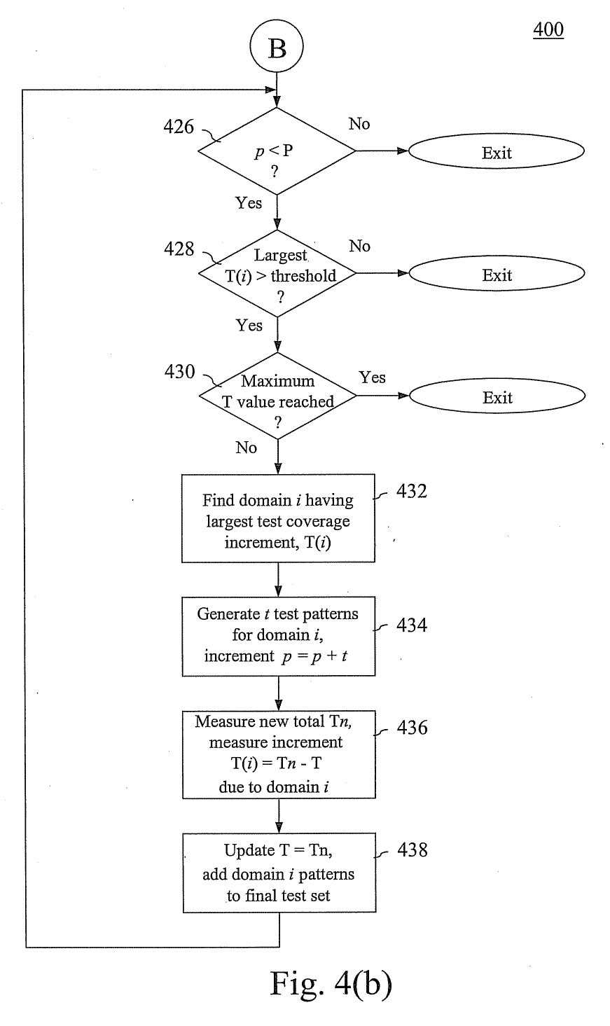

Referring now to FIGS. 4(a) and 4(b), there is shown a flowchart 400 illustrating one possible detailed implementation of the method in FIG. 3. Beginning at block 402, various parameters are defined and initialized. For instance, the total test coverage, T, for the IC device is initialized to 0. In addition, N is defined as the total number of domains (e.g., clock domains) for which the test patterns are to be generated; P is defined as the total number of test patterns available due to tester memory size or other related constraints, and p represents a running total of the actual number of test patterns that have been generated for the IC device. Thus, p would also be initialized to 0 at the beginning of the process.

Block 404 begins an initial loop sequence in which, for each of the N domains, a subset t of test patterns are generated. In decision block 406, it is determined whether the t patterns actually exceeds the maximum amount of patterns that are required to completely test the current Domain i. Thus, if less than t patterns are generated for Domain i, then those patterns are immediately added to the final test set in block 408. A flag is then set in block 410 so that the current domain will not have any further test patterns generated therefor. Then, in block 412, the running total p of generated patterns is updated by however many patterns were actually generated for Domain i. In block 414, the value of i is incremented and the process loops back to block 404 so long as i has not yet exceeded the total number N of domains as reflected in decision block 416.

However, assuming at decision block 406 that the full subset of t patterns can be generated for Domain i, then the running total p is updated by adding t to the previous total of p, as shown in block 418. Then, in block 420, the total new test coverage, Tn, as a result of the generation of the t test patterns to Domain i is measured. From this value, the incremental change in total test coverage, T(i), due to Domain i is determined in block 422, wherein T(i)=Tn−T. Next, in block 424, the old value of T is updated to equal the new value Tn, and the t patterns generated for Domain i are added to the final test set. The process then proceeds to block 414 as described above, where i is incremented, thereafter looping back to block 404 until i eventually exceeds the total number N of domains (i.e., test patterns have been generated for each domain one time. Once this condition has been reached, the process advances to path B as depicted in FIG. 4(b).

As indicated in the general process flow of FIG. 3, once test patterns have been generated for each domain and the incremental increase in total test coverage due to each determined, the process is iteratively repeated by generating the next subset of t patterns for the domain currently providing the largest incremental test coverage until one or more threshold criteria is reached. The exemplary threshold criteria are depicted in decision blocks 426, 428 and 430. More specifically, block 426 provides an exit once the running total of generated test patterns p is no longer less than the maximum number of available test patterns P. In addition, decision block 428 provides an exit once the largest current incremental change in test coverage fails to exceed a selected threshold value, in the event the continued generation of test patterns results in diminishing returns. Furthermore, decision block 430 provides a process exit where a maximum defined total test coverage is exceeded.

Provided none of the exit conditions are met, the process continues to block 432, in which the Domain i, currently having the largest test coverage, T(i), is identified. In block 434, t test patterns are generated for Domain i, and the running total p is updated to reflect the additional t patterns. Then, in block 436, the total new test coverage, Tn, as a result of the generation of the t test patterns for Domain i is measured. From this value, the incremental change in total test coverage, T(i), due to Domain i is determined, wherein T(i)=Tn−T. Finally, in block 438, the old value of T is updated to equal the new value Tn, and the t patterns generated for Domain i are added to the final test set.

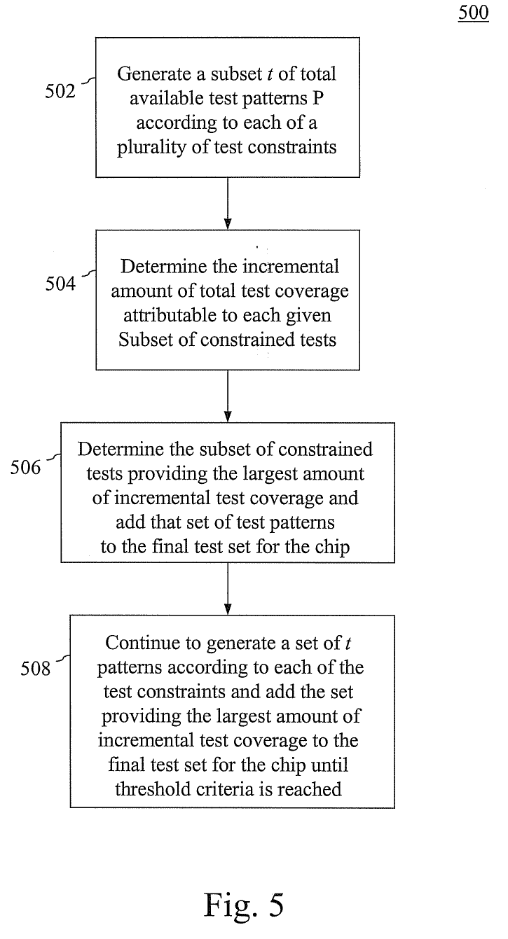

FIG. 5 is a high-level process flow diagram illustrating a method 500 for maximizing the total test coverage for the IC device by generating test patterns according to one test constraint at a time, in accordance with another exemplary embodiment of the invention. As shown in block 502, the method 500 begins by generating a subset, t, of the total number of test patterns according to each of a plurality of test constraints. Again, in the simple example of FIG. 1, each test constraint corresponds to a particular clock domain of the IC device, and the total number, N, of domains (e.g., asynchronous clock domains) is equal to 3. After t patterns are generated for each of the domains, the resulting incremental chip test coverage attributable to each domain is determined, as shown in block 504.

An underlying principle of the alternative inventive embodiment is the subsequent generation/allocation of additional test patterns for each test constraint, and the addition of only the patterns of that test constraint that yields the largest incremental test coverage to the final test set, as reflected in block 506. Thus, in the simplified example used herein, if the generation of 32 test patterns for each of Domains 1, 2 and 3 of FIG. 1 resulted in incremental test coverages of 2% for Domain 1, 7% for Domain 2 and 5% for Domain 3, then Domain 2 has provided the largest incremental test coverage, and only its test patterns would be added to the final test set.

As reflected in block 508, the process is iteratively repeated by generating a subset of patterns for each domain, and only the patterns of the domain currently providing the largest incremental test coverage are added to the final test set, until one or more threshold criteria is reached. Such criteria may include, for example: the total number of generated test patterns equaling or exceeding a selected maximum value; the total test coverage from all of the generated patterns equaling or exceeding a selected maximum value; the largest incremental test coverage among the domains falling below a selected minimum value. In this manner, the respective performance of the domains is repeatedly evaluated, so that the test patterns can be more efficiently distributed.

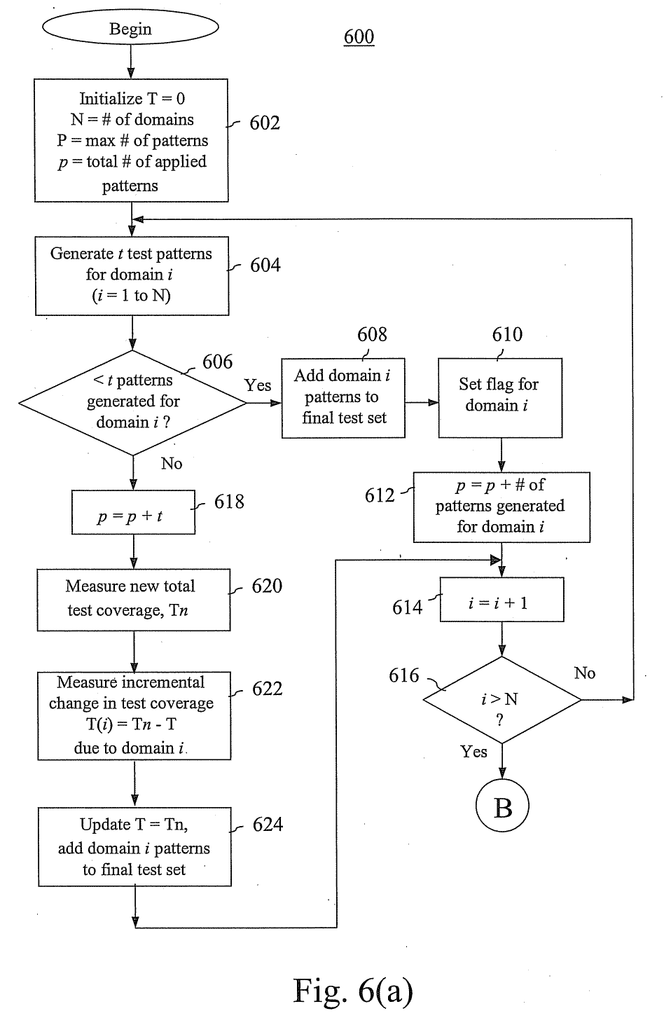

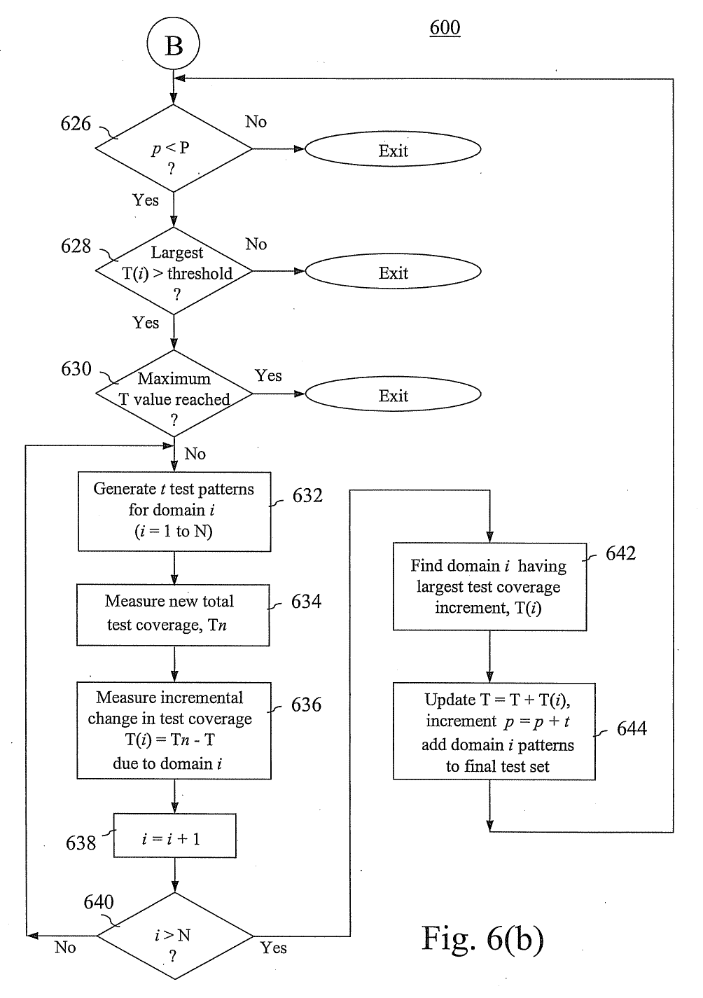

Referring now to FIGS. 6(a) and 6(b), there is shown a flowchart 600 illustrating one possible detailed implementation of the method in FIG. 5. Beginning at block 602, various parameters are defined and initialized. For instance, the total test coverage, T, for the IC device is initialized to 0. In addition, N is defined as the total number of domains (e.g., clock domains) for which the test patterns are to be generated; P is defined as the total number of test patterns available due to tester memory size or other related constraints, and p represents a running total of the actual number of test patterns that have been generated for the IC device. Thus, p would also be initialized to 0 at the beginning of the process.

Block 604 begins an initial loop sequence in which, for each of the N domains, a subset t of test patterns is generated. In decision block 606, it is determined whether the t patterns actually exceeds the maximum amount of patterns that are required to completely test the current Domain i. Thus, if less than t patterns are generated for Domain i, then those patterns are immediately added to the final test set in block 608. A flag is then set in block 610 so that the current domain will not have any further test patterns generated therefor. Then, in block 612, the running total p of generated patterns is updated by however many patterns were actually generated for Domain i. In block 614, the value of i is incremented and the process loops back to block 604 so long as i has not yet exceeded the total number N of domains as reflected in decision block 616.

However, assuming at decision block 606 that the full subset of t patterns can be generated for Domain i, then the running total p is updated by adding t to the previous total of p, as shown in block 618. Then, in block 620, the total new test coverage, Tn, as a result of the generation of the t test patterns for Domain i is measured. From this value, the incremental change in total test coverage, T(i), due to Domain i is determined in block 622, wherein T(i)=Tn−T. Next, in block 624, the old value of T is updated to equal the new value Tn, and the t patterns generated for Domain i are added to the final test set. This ensures that each domain receives at least t patterns. The process then proceeds to block 614 as described above, where i is incremented, thereafter looping back to block 604 until i eventually exceeds the total number N of domains (i.e., test patterns have been generated for each domain one time. Once this condition has been reached, the process advances to path B as depicted in FIG. 6(b).

As indicated in the general process flow of FIG. 5, once test patterns have been generated for each domain, the incremental increase in total test coverage due to each determined and the patterns for the domain providing the largest incremental increase in total test coverage have been added to the final test set, the process is iteratively repeated by generating the next subset of t patterns for each domain until one or more threshold criteria is reached. The exemplary threshold criteria are depicted in decision blocks 626, 628 and 630 as previously described for FIG. 4(b).

Provided none of the exit conditions are met, the process continues to block 632, in which begins a loop sequence in which, for each of the N domains, a subset t of test patterns are generated. In block 634, the total new test coverage, Tn, as a result of the generation of the t test patterns for Domain i is measured. From this value, the incremental change in total test coverage, T(i), due to Domain i is determined in block 636, wherein T(i)=Tn−T. In block 638, i is incremented, thereafter looping back to block 632 until i eventually exceeds the total number N of domains.

In block 642, the Domain i having the largest increment to the total test coverage T(i) is determined, and its patterns are added to the final test set in block 644. The total test coverage T is updated to T+T(i) and the value of p is updated to p+t.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for automatically generating test patterns for an IC device, the method comprising:
initially generating a subset of available test patterns for each of a plurality of test constraints for the IC device;
determining an incremental amount of total test coverage of the IC device attributable to each of the subsets of constrained test patterns as a result of the initially generated subsets of test patterns therefor;
determining the test constraint initially providing the largest amount of incremental test coverage, and thereafter generating another subset of test patterns therefor; and
iteratively determining the current test constraint providing the largest amount of incremental test coverage, and continuing to generate additional test patterns therefor until one or more test exit criteria is reached.

2. The method of claim 1, wherein the one or more test exit criteria further comprise at least one of:
a total number of generated test patterns exceeding a defined maximum value;
the total test coverage of the IC device exceeding a defined maximum value; and
the largest amount of incremental test coverage falling below a defined minimum value.

3. The method of claim 1, wherein the test constraints comprise one or more of: asynchronous clock domains, circuit partitions, test modes and test generation algorithms.

4. The method of claim 1, further comprising adding each generated subset of available test patterns to a final test set for the IC device.

5. The method of claim 1, further comprising discontinuing generating additional subsets of test patterns for a given test constraint in the event the number of test patterns in a subset exceeds the total amount of patterns that are required to test the IC device restricted by the given test constraint.

6. A method for generating test patterns for an IC device, the method comprising:
initializing a total test coverage amount, T, of the IC device to zero, wherein T represents a ratio of total tested faults of the IC device to an actual number of faults of the IC device;
initially generating a subset, t, of a maximum number, P, of available test patterns for each of a number, N, of test constraints of the IC device;
accumulating a running total, p, of generated test patterns for the IC upon generation of the t test patterns for each of the N test constraints, and adding each generated subset of t test patterns to a final test set for the IC device;
determining a new total test coverage value, Tn, upon each generation of t test patterns;
determining an incremental amount of total test coverage of the IC device attributable to each of the test constraints as a result of the generated subset of test patterns therefor, wherein the incremental amount of total test coverage, T(i) of a given test constraint, i, is determined by the difference between the new total test coverage value and the previous total test coverage amount, T, such that T(i)=Tn−T;
updating the total test coverage amount, T, to reflect the new total test coverage value, Tn, such that T=Tn;
identifying a specific test constraint, i, initially providing the largest amount of incremental test coverage, T(i), with respect to the other test constraints, and thereafter generating another subset of t test patterns therefor;
and iteratively determining the current test constraint providing the largest amount of incremental test coverage, and continuing to generate additional t test patterns therefor until one or more test exit criteria is reached.

7. The method of claim 6, wherein the one or more test exit criteria further comprise at least one of:
the total number of generated test patterns, p, exceeding a defined maximum value;
the total test coverage, T, of the IC device exceeding a defined maximum value; and
the largest amount of incremental test coverage falling below a defined minimum value.

8. The method of claim 6, wherein the test constraints comprise one or more of: asynchronous clock boundaries, circuit partitions, test modes and test generation algorithms.

9. The method of claim 6, further comprising discontinuing generating additional subsets of t test patterns for a given test constraint in the event t exceeds the total amount of patterns that are required to completely test the IC when restricted by the given test constraint.

10. The method of claim 6, wherein iteratively determining the current test constraint providing the largest amount of incremental test coverage further comprises:
determining a new total test coverage value, Tn, upon each generation of t test patterns for Domain i;
and determining an incremental amount of total test coverage of the IC device attributable to Domain i as a result of the generated subset of t test patterns therefor, wherein the incremental amount of total test coverage, T(i) for Domain i is determined by the difference between the new total test coverage value and the previous total test coverage amount, T, such that T(i)=Tn−T.

11. A method for automatically generating test patterns for an IC device, the method comprising:
initially generating a subset of available test patterns for each of a plurality of test constraints for the IC device;
determining an incremental amount of total test coverage of the IC device attributable to each of the subsets of constrained test patterns as a result of the initially generated subsets of test patterns therefor;
determining the test constraint initially providing the largest amount of incremental test coverage, and adding its subset of patterns to a final test set; and
continuing to iteratively generate an additional subset of patterns for each test constraint, determining the test constraint providing the largest amount of incremental test coverage, and adding its subset of patterns to the final test set, until one or more test exit criteria is reached.

12. The method of claim 11, wherein the one or more test exit criteria further comprise at least one of:
a total number of generated test patterns exceeding a defined maximum value;
the total test coverage of the IC device exceeding a defined maximum value; and
the largest amount of incremental test coverage falling below a defined minimum value.

13. The method of claim 11, wherein the test constraints comprise one or more of: asynchronous clock domains, circuit partitions, test modes and test generation algorithms.

14. The method of claim 1, further comprising discontinuing generating additional subsets of test patterns for a given test constraint in the event the number of test patterns in a subset exceeds the total amount of patterns that are required to test the IC device restricted by that given test constraint.

15. A method for generating test patterns for an IC device, the method comprising: initializing a total test coverage amount, T, of the IC device to zero, wherein T represents a ratio of total tested faults of the IC device to an actual number of faults of the IC device;
initially generating a subset, t, of a maximum number, P, of available test patterns for each of a number, N, of test constraints of the IC device;
adding each generated subset of t test patterns to a final test set for the IC device, and accumulating a running total, p, of added test patterns to the IC upon addition of the t test patterns for each of the N test constraints;
determining a new total test coverage value, Tn, upon each generation of t test patterns;
determining an incremental amount of total test coverage of the IC device attributable to each of the test constraints as a result of the generated subset of test patterns therefor, wherein the incremental amount of total test coverage, T(i), of a given test constraint, i, is determined by the difference between the new total test coverage value and the previous total test coverage amount, T, such that T(i)=Tn−T;
updating the total test coverage amount, T, to reflect the new total test coverage value, Tn, such that T=Tn; again generating a subset, t, of a maximum number, P, of available test patterns for each of a number, N, of test constraints of the IC device, identifying a specific test constraint, i, providing the largest amount of incremental test coverage, T(i), with respect to the other test constraints, adding only the subset of patterns generated for test constraint i to the final test set, and incrementing p by the number t of test patterns added to the final test set;
iteratively generating a subset, t, of a maximum number, P, of available test patterns for each of a number, N, of test constraints of the IC device, identifying a specific test constraint, i, providing the largest amount of incremental test coverage, T(i), with respect to the other test constraints, adding only the subset of patterns generated for test constraint i to the final test set, and incrementing p by the number t of test patterns added to the final test set until one or more test exit criteria is reached.

16. The method of claim 15, wherein the one or more test exit criteria further comprise at least one of:
the total number of generated test patterns, p, exceeding a defined maximum value;
the total test coverage, T, of the IC device exceeding a defined maximum value; and
the largest amount of incremental test coverage falling below a defined minimum value.

17. The method of claim 15, wherein the test constraints comprise one or more of: asynchronous clock boundaries, circuit partitions, test modes and test generation algorithms.

18. The method of claim 15, further comprising discontinuing generating additional subsets of t test patterns for a given test constraint in the event t exceeds the total amount of patterns that are required to completely test the IC when restricted by the given test constraint.

19. The method of claim 15, wherein iteratively determining the current test constraint providing the largest amount of incremental test coverage further comprises:
determining a new total test coverage value, Tn, upon each generation of t test patterns to Domain i; and
determining an incremental amount of total test coverage of the IC device attributable to Domain i as a result of the generated subset of t test patterns therefor, wherein the incremental amount of total test coverage, T(i) of Domain i is determined by the difference between the new total test coverage value and the previous total test coverage amount, T, such that T(i)=Tn−T.
